(19) United States
(12) Patent Application Publication
(10) Pub. No.: US 2026/0291463 A1
(43) Pub. Date: Sep. 24, 2026

(54) ELASTIC WAVE RESONATOR AND COMMUNICATION DEVICE

(71) Applicant: KYOCERA CORPORATION, Kyoto-shi, Kyoto (JP)

(72) Inventors: Soichiro NOZOE, Soraku-gun, Kyoto (JP); Takashi KATO, Yasu-shi, Shiga (JP)

(73) Assignee: KYOCERA CORPORATION, Kyoto-shi, Kyoto (JP)

(21) Appl. No.: 19/474,201

(22) PCT Filed: Apr. 19, 2024
(86) PCT No.: PCT/JP2024/015526

§ 371 Date: Oct. 10, 2025

(30) Foreign Application Priority Data
Apr. 25, 2023 (JP) 2023-071664

(51) Int. Cl. H03H 9/13; H03H 9/02; H03H 9/17

(52) U.S. Cl. CPC H03H 9/132; H03H 9/02228; H03H 9/173; H03H 9/175; H03H 9/176

(57) ABSTRACT

An acoustic wave resonator includes a piezoelectric body layer including a first surface provided with a groove and having piezoelectric properties, and a plurality of electrode fingers including a first electrode finger at least partially positioned in the groove. In a sectional view in an extension direction of the plurality of electrode fingers, a region of the first electrode finger positioned in the groove includes a wide region and a narrow region smaller in width than the wide region. The acoustic wave resonator excites at least one of a plate wave or a bulk wave as main resonance.

### TECHNICAL FIELD

The present disclosure relates to an acoustic wave resonator as an electronic component utilizing an acoustic wave, and a communication device including the acoustic wave resonator.

### BACKGROUND OF INVENTION

Patent Literature 1 discloses an acoustic wave device including a piezoelectric layer and an interdigital transducer (IDT) electrode positioned on the piezoelectric layer, and is configured to utilize a plate wave in an A1 mode as an acoustic wave. The IDT electrode includes a plurality of electrode fingers arrayed in a propagation direction of the acoustic wave. A smaller pitch of the plurality of electrode fingers leads to a higher resonance frequency. According to Patent Literature 1, the acoustic wave device adopts a pitch equal to that of resonators configured to utilize a conventional surface acoustic wave as main resonance, so as to achieve resonance in a higher frequency wave region in comparison to a conventional case.

### CITATION LIST

### Patent Literature

Patent Literature 1: International Publication No. 2020/100949

### SUMMARY

According to an embodiment of the present disclosure, an acoustic wave resonator includes a piezoelectric body layer and a plurality of electrode fingers. The piezoelectric body layer includes a first surface provided with a groove and has piezoelectric properties. The plurality of electrode fingers includes a first electrode finger at least partially positioned in the groove. In a sectional view as viewed in an extension direction of the plurality of electrode fingers, a region of the first electrode finger positioned in the groove includes a wide region and a narrow region smaller in width than the wide region. The acoustic wave resonator excites at least one of a plate wave or a bulk wave as main resonance.

According to an embodiment of the present disclosure, a communication device includes an antenna, an acoustic wave filter, and an integrated circuit (IC). The acoustic wave filter is connected to the antenna. The IC is connected to the acoustic wave filter The acoustic wave filter includes the acoustic wave resonator.

### BRIEF DESCRIPTION OF THE DRAWINGS

FIG. 1 is a schematic sectional view of an acoustic wave resonator according to an embodiment of the present disclosure.

FIG. 2 is a schematic plan view of an acoustic wave resonator according to an embodiment of the present disclosure.

FIGS. 3A and 3B are schematic sectional views of electrode fingers of an acoustic wave resonator according to an embodiment of the present disclosure.

FIG. 4 is a graph indicating simulation results of resonance characteristics of an acoustic wave resonator according to an embodiment of the present disclosure.

FIGS. 5A, 5B, and 5C are schematic sectional views of electrode fingers of an acoustic wave resonator according to a different embodiment of the present disclosure.

FIG. 6 is a schematic sectional view of the acoustic wave resonator according to the different embodiment of the present disclosure.

FIGS. 7A and 7B are graphs indicating simulation results of frequency characteristics according to examples of the present disclosure.

FIGS. 8A and 8B are graphs indicating simulation results of the frequency characteristics according to the examples of the present disclosure.

FIGS. 9A and 9B are graphs indicating simulation results of frequency characteristics according to examples of the present disclosure.

FIGS. 10A and 10B are graphs indicating simulation results of the frequency characteristics according to the examples of the present disclosure.

FIG. 11 is a schematic view of a branching filter exemplarily utilizing an acoustic wave resonator according to an embodiment of the present disclosure.

FIG. 12 is a block diagram illustrating a configuration of a principal part of a communication device exemplarily utilizing an acoustic wave resonator according to an embodiment of the present disclosure.

### DESCRIPTION OF EMBODIMENTS

Described hereinafter with reference to the drawings are an acoustic wave resonator and a communication device according to an embodiment of the present disclosure. The drawings to be referred to in the following description are schematic drawings, size ratios and the like on which do not necessarily match those of any actual acoustic wave resonator and any communication device.

The drawings may be provided with an orthogonal coordinate system including an X axis, a Y axis, and a Z axis. The X axis is defined to be parallel to a propagation direction of an acoustic wave to be utilized as main resonance out of acoustic waves propagating in a piezoelectric body layer 2 to be described later. The Y axis is defined to be parallel to an extension direction of an electrode finger 412 to be described later. The Z axis is defined to be perpendicular to an upper surface 2a of the piezoelectric body layer 2 to be described later. The present disclosure exemplarily adopts the orthogonal coordinate system, and the X axis, the Y axis, and the Z axis may be defined differently in direction from those of the orthogonal coordinate system adopted in the present disclosure. The present disclosure may use a term of an upper surface or a lower surface assuming that the Z axis extends vertically for convenience.

The present disclosure exemplarily provides acoustic wave resonators according to respective embodiments. Accordingly, configurations may be replaced partially between different embodiments. Furthermore, different embodiments may be combined partially.

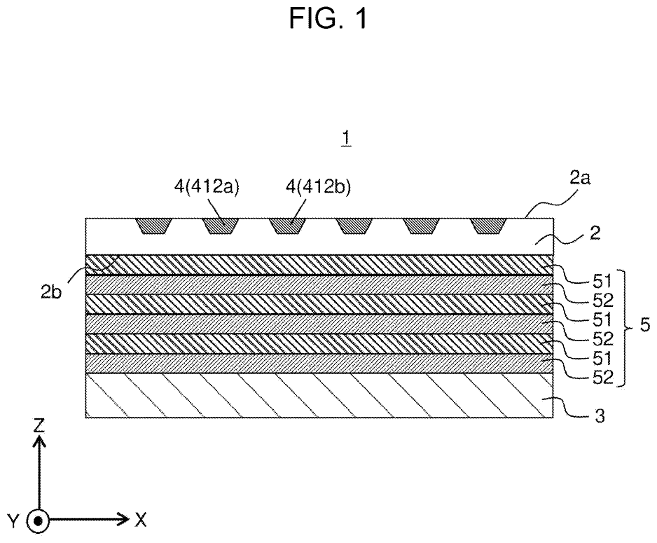

FIG. 1 is a schematic sectional view in the Y axis direction of an acoustic wave resonator 1 according to an embodiment of the present disclosure. As illustrated in FIG. 1, in an embodiment of the present disclosure, the acoustic wave resonator 1 includes the piezoelectric body layer 2, a support substrate 3, an acoustic reflective layer 5, and an IDT electrode 4.

The piezoelectric body layer 2 includes the upper surface 2a and a lower surface 2b disposed perpendicularly to the Z axis that is assumed to be disposed vertically. The lower surface 2b is positioned opposite to the upper surface 2a. The upper surface 2a and the lower surface 2b may be exemplarily called a first surface and a second surface, respectively. The acoustic reflective layer 5 and the support substrate 3 to be described later are positioned adjacent to the lower surface 2b of the piezoelectric body layer 2. The IDT electrode 4 to be described later is positioned adjacent to the upper surface 2a of the piezoelectric body layer 2.

The piezoelectric body layer 2 contains a material having piezoelectric properties. Examples of the material having piezoelectric properties include a single crystal of lithium tantalate (LiTaO₃; hereinafter, referred to as LT) and a single crystal of lithium niobate (LiNbO₃; hereinafter, referred to as LN).

The piezoelectric body layer 2 has piezoelectric properties, and an acoustic wave propagating in the piezoelectric body layer 2 is excited when a radio-frequency signal is applied to the IDT electrode 4. In an embodiment of the present disclosure, an acoustic wave to be excited as main resonance includes at least one of a plate wave or a bulk wave.

In an embodiment of the present disclosure, the plate wave or the bulk wave to be exited as main resonance is not particularly limited in type and propagation mode, which may be set in accordance with required frequency characteristics. The piezoelectric body layer 2 contains a piezoelectric single crystal having Euler angles (φ, θ, ψ) that may be designed as appropriate in accordance with the type, the propagation mode, and the like of the plate wave or the bulk wave to be utilized as main resonance. Examples of the type of the plate wave can include a Lamb wave and an SH wave. Examples of the propagation mode of the Lamb wave can include an A1 mode as an asymmetric mode and an S mode as a symmetric mode. Examples of the type of the bulk wave can include a wave propagating in a planar direction of the piezoelectric body layer 2 and a wave propagating in a thickness direction of the piezoelectric body layer 2. Specifically in an embodiment of the present disclosure, the acoustic wave to be excited as main resonance is in the A1 mode of the Lamb wave as a plate wave.

When the piezoelectric body layer 2 exemplarily contains LT, the Euler angles (φ, θ, ψ) of the LT are set to (0°±10°, 0° or more and 55° or less, 0°±10°) or angles crystallographically equivalent to these angles, so as to effectively utilize the A1 mode of the Lamb wave as main resonance. The Euler angles (φ, θ, ψ) may alternatively be set to (0°±10°, 30°±10°, 0°±10°) or angles crystallographically equivalent to these angles with reference to examples 1 and 2 to be described later. When the piezoelectric body layer 2 contains LN, the Euler angles (φ, θ, ψ) of the LN are set to (0°±10°, 0° or more and 55° or less, 0°±10°) or angles crystallographically equivalent to these angles, so as to effectively utilize the A1 mode of the Lamb wave as main resonance. The Euler angles (φ, θ, ψ) may alternatively be set to (0°±10°, 35°±10°, 0°±10°) or angles crystallographically equivalent to these angles with reference to examples 3 and 4 to be described later.

Main resonance exemplarily indicates a resonance having the smallest one of an impedance minimum value (from a different viewpoint, impedance in a resonance frequency) out of a plurality of resonances different in resonance frequency and generated in the acoustic wave resonator 1. The expression that a specific acoustic wave (e.g., a plate wave) is utilized as main resonance exemplarily means that the specific acoustic wave is a main component of acoustic waves generating main resonance. Examples of the main component include a component occupying 50% or more or 80% or more of energy of an acoustic wave in a resonance frequency. When both a plate wave and a bulk wave are utilized as main resonance, entire energy of the both waves has only to have such a value as described above (each of the waves may be less than the lower limit described above).

The piezoelectric body layer 2 has a thickness equal to or less than a wavelength λ to be described later. When the thickness of the piezoelectric body layer 2 is set to λ or less, at least one of the plate wave or the bulk wave can be utilized effectively as main resonance. The thickness of the piezoelectric body layer 2 may alternatively be 0.5 λ or less. In this case, at least one of the plate wave or the bulk wave can be utilized more effectively as main resonance. The thickness of the piezoelectric body layer 2 may still alternatively be set to 0.4 λ or less or 0.3 λ or less. No particular lower limit is set, and the piezoelectric body layer 2 may be made as thin as possible. For example, the thickness of the piezoelectric body layer 2 may be set to 0.05 λ or more, 0.10 λ or more, or 0.15 λ or more. Any appropriate lower and upper limits mentioned above may be combined with each other.

The support substrate 3 is positioned adjacent to the lower surface 2b of the piezoelectric body layer 2. The support substrate 3 is not particularly limited in thickness and may be exemplarily thicker than the piezoelectric body layer 2.

The support substrate 3 is not particularly limited in terms of its material. The material for the support substrate 3 may be exemplarily smaller in linear expansion coefficient than the material for the piezoelectric body layer 2. Such a material for the support substrate 3 can reduce deformation of the piezoelectric body layer 2 due to temperature changes and can reduce changes in the resonance characteristics of the acoustic wave resonator 1 due to temperature changes. Examples of the material for the support substrate 3 can include sapphire (Al₂O₃), silicon carbide (SiC), and silicon (Si).

The acoustic reflective layer 5 is positioned adjacent to the lower surface 2b (in direct or indirect contact with the lower surface 2b) of the piezoelectric body layer 2, and is positioned between the piezoelectric body layer 2 and the support substrate 3. The acoustic reflective layer 5 is different in acoustic impedance from the piezoelectric body layer 2. In this case, the piezoelectric body layer 2 and the acoustic reflective layer 5 have a difference in acoustic impedance so as to effectively confine an acoustic wave to be excited in the piezoelectric body layer 2.

The acoustic reflective layer 5 may be constituted by a single layer or a plurality of layers. For example, the acoustic reflective layer 5 may include a plurality of low acoustic impedance layers 51 and a plurality of high acoustic impedance layers 52 stacked alternately. The low acoustic impedance layers 51 are smaller in acoustic impedance than the piezoelectric body layer 2. The high acoustic impedance layers 52 are larger in acoustic impedance than the low acoustic impedance layers 51. In such a configuration, an acoustic wave leaking from the lower surface 2b of the piezoelectric body layer 2 is reflected toward the piezoelectric body layer 2 at each interface between the low acoustic impedance layer 51 and the high acoustic impedance layer 52 so as to effectively reduce leakage of the acoustic wave.

Examples of the low acoustic impedance layers 51 can include silicon oxide (SiO₂). Examples of the high acoustic impedance layers 52 can include hafnium oxide (HfO₂), tantalum oxide (Ta₂O₅), tungsten (W), molybdenum (Mo), and zirconium oxide (ZrO₂).

The IDT electrode 4 is positioned adjacent to the upper surface 2a of the piezoelectric body layer 2. The IDT electrode 4 is made of a material having conductivity. Examples of the material for the IDT electrode 4 can include various conductive materials such as aluminum (Al), copper (Cu), platinum (Pt), molybdenum (Mo), gold (Au), and alloys of any of these materials. The IDT electrode 4 may include a plurality of stacked layers made of the various conductive materials. When the IDT electrode 4 includes the plurality of stacked layers, a diffusion prevention layer made of a metal such as titanium (Ti) or a dielectric may be interposed at each interface between the stacked layers. In the plurality of layers of the IDT electrode 4, a layer positioned adjacent to the piezoelectric body layer 2 may serve as a ground layer made of a metal such as titanium (Ti) or a dielectric. In an embodiment of the present disclosure, the IDT electrode 4 is specifically made of Al.

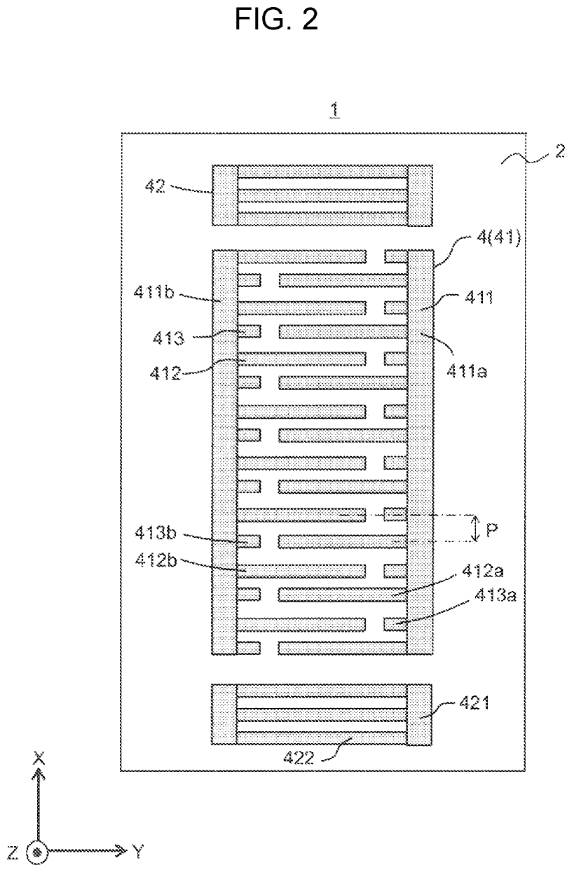

FIG. 2 is a plan view in the Z axis direction of the acoustic wave resonator 1 according to an embodiment of the present disclosure. As illustrated in FIG. 2, the IDT electrode 4 includes a comb-shaped electrode 41. The comb-shaped electrode 41 includes a plurality of electrode fingers 412 being arrayed. The comb-shaped electrode 41 further includes a pair of bus bars 411 positioned in a direction crossing an array direction of the plurality of electrode fingers 412 and connected to the plurality of electrode fingers 412. In other words, the plurality of electrode fingers 412 extends from the bus bars 411. The plurality of electrode fingers 412 is disposed such that a plurality of electrode fingers 412a connected to a first bus bar 411a and electrode fingers 412b connected to a second bus bar 411b mesh each other. In an embodiment as illustrated in FIG. 2, the array direction of the plurality of electrode fingers 412 is along the X axis, and the extension direction of the plurality of electrode fingers 412 is along the Y axis.

The comb-shaped electrode 41 may include a plurality of dummy electrode fingers 413 positioned between adjacent ones of the plurality of electrode fingers 412. The plurality of dummy electrode fingers 413 includes a plurality of dummy electrode fingers 413a connected to the first bus bar 411a and facing the electrode fingers 412b extending from the second bus bar 411b, and a plurality of dummy electrode fingers 413b connected to the second bus bar 411b and facing the electrode fingers 412a extending from the first bus bar 411a. In the present disclosure, the expression “facing” does not necessarily require that facing surfaces are parallel to each other, and the facing surfaces may be inclined from each other.

Each of the electrode fingers 412 has a length in the extension direction, which may be set as appropriate in accordance with required electrical characteristics and the like. The plurality of electrode fingers 412 exemplarily has equal lengths in the extension direction. The IDT electrode 4 may be provided with so-called apodization such that the lengths in the extension direction of the plurality of electrode fingers 412 are varied in accordance with positions in the X axis direction.

The plurality of electrode fingers 412 has a repetition interval in the array direction to be referred to as a pitch P. The pitch P is designed as appropriate in accordance with desired frequency characteristics. The pitch P is constant in FIG. 2, but is not limited to this exemplification. For example, the pitch P may be designed to gradually increase, or may be designed to step wisely have a plurality of types of repetition intervals. When the pitch P includes a plurality of different repetition intervals, the pitch P may be defined as an average value of repetition intervals measured at five to ten locations, or may be defined to represent the largest repetition interval. The pitch P has a specific value determined as appropriate. For example, the pitch P may be 0.5 μm or more, or 1 μm or more, and may be 10 μm or less, 5 μm or less, or 2 μm or less. Any appropriate lower and upper limits exemplified above may be combined with each other. Specifically in an embodiment of the present disclosure, the pitch P of the electrode fingers 412 is 1.1 μm.

When a radio-frequency signal is applied to the IDT electrode 4, an acoustic wave having the wavelength λ defined to be twice the pitch P as the repetition interval of the plurality of electrode fingers 412 is excited and propagates in the piezoelectric body layer 2. Unlike the above case, the wavelength λ may alternatively be less dependent on the pitch P as the bulk wave propagating in the thickness direction of the piezoelectric body layer 2. The wavelength λ used for definition of the thicknesses of the piezoelectric body layer 2 and the like has only to be twice the pitch P, and may deviate from the wavelength of the acoustic wave to be excited as main resonance.

In an embodiment of the present disclosure, the acoustic wave resonator 1 may further include (but does not necessarily include) a pair of reflectors 42 positioned adjacent to the upper surface 2a of the piezoelectric body layer 2. The pair of reflectors 42 are exemplarily positioned on both sides of the comb-shaped electrode 41 in the X axis direction. The reflectors 42 each include a pair of reflector bus bars 421 facing each other and a plurality of strip electrodes 422 extending between the pair of reflector bus bars 421.

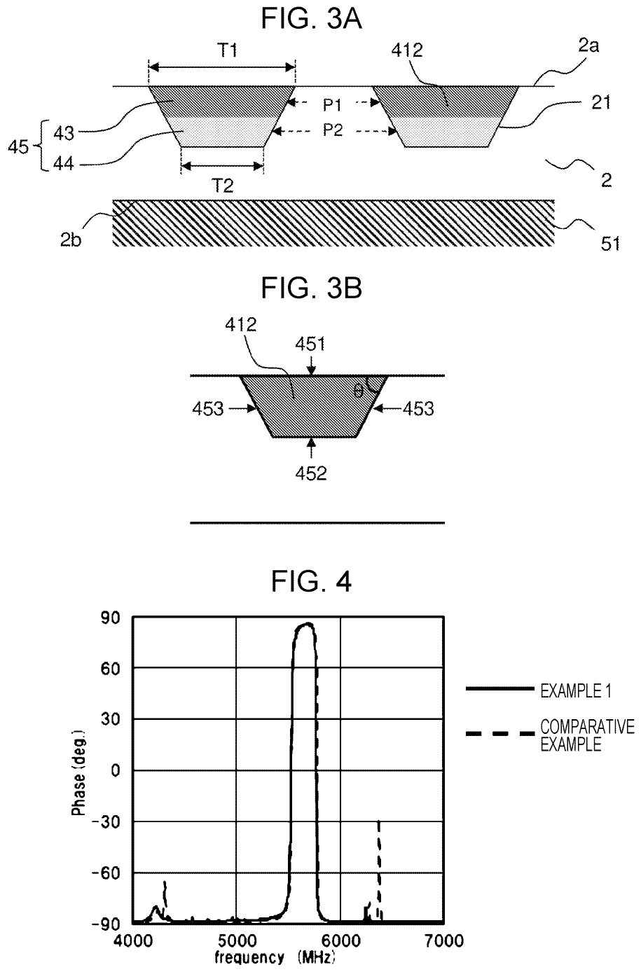

FIGS. 3A and 3B are schematic sectional views in the Y axis direction of the acoustic wave resonator 1 according to an embodiment of the present disclosure, and illustrate enlarged portions including the electrode fingers 412. In other words, FIGS. 3A and 3B illustrate sectional views as viewed in the extension direction of the electrode fingers 412.

In the acoustic wave resonator 1 according to an embodiment of the present disclosure, the piezoelectric body layer 2 includes a groove 21 provided in the upper surface 2a. At least part of the plurality of electrode fingers 412 is positioned in the groove 21. All the plurality of electrode fingers 412 may be positioned in the groove 21, but the plurality of electrode fingers 412 is not limited to this exemplification. For example, the plurality of electrode fingers 412 may include both the electrode finger 412 positioned in the groove 21 and the electrode finger 412 positioned outside the groove 21. Thickness (or at least one of thickness or volume) of the electrode finger 412 positioned in the groove 21 may be entirely positioned in the groove 21. The disposition is not limited to this exemplification. For example, at least part (e.g., a lower portion) of the thickness (or at least one of the thickness or the volume) of the electrode finger 412 has only to be positioned in the groove 21. A region positioned in the groove 21 of the electrode finger 412 may be called an embedded region 45 for distinction from a protruding region 46 to be described later.

As illustrated in FIG. 3A, the embedded region 45 positioned in the groove 21 of the electrode finger 412 includes a wide region 43 and a narrow region 44. The narrow region 44 of the electrode finger 412 is smaller in width than the wide region 43 of the electrode finger 412. In other words, assuming that the wide region 43 of the electrode finger 412 has a width T1 and the narrow region 44 of the electrode finger 412 has a width T2, T1>T2 is established. Note that the width T1 may be located at any position in the wide region 43, and that the width T2 may be located at any position in the narrow region 44. For example, the width T1 may be located at the widest position in the wide region 43, and the width T2 may be located at the narrowest position in the narrow region 44. The “width” of the electrode finger 412 corresponds to the length of the electrode finger 412 in the X axis direction.

Where the narrow region 44 and the wide region 43 are located in the electrode finger 412 can be determined by comparison in width between positions to be measured. A region smaller in width than the narrowest position in the wide region 43 is assumed as the narrow region 44, whereas a region larger in width than the widest position in the narrow region 44 is assumed as the wide region 43. In other words, the entire wide region 43 is larger in width than the entire narrow region 44, and the entire narrow region 44 is smaller in width than the entire wide region 43. The embedded region 45 of the electrode finger 412 may include a plurality of wide regions 43 or a plurality of narrow regions 44.

As illustrated in FIG. 3B, according to an embodiment of the present disclosure, a specific section in an extending direction of the electrode finger 412 has a trapezoidal shape including an upper base 451 as a main surface positioned adjacent to an opening of the groove 21, a lower base 452 as a main surface positioned adjacent to a bottom of the groove 21, and legs 453 as side surfaces. When the section in the extending direction of the electrode finger 412 has the trapezoidal shape in this manner, the narrow region 44 is positioned closer to the lower surface 2b of the piezoelectric body layer 2 than the wide region 43.

When the embedded region 45 of each of the electrode fingers 412 includes the wide region 43 and the narrow region 44 as in an embodiment of the present disclosure, a pitch P1 of the electrode fingers 412 in the wide regions 43 can be set differently from a pitch P2 of the electrode fingers 412 in the narrow regions 44. The pitch P described above is a parameter uninfluenced by the width of the electrode fingers 412, and examples thereof include a distance between the centers of the electrode fingers 412 adjacent to each other. The pitches P1 and P2 are parameters influenced by the width of the electrode fingers 412, and examples thereof include a distance (interval) between the side surfaces of the electrode fingers 412 adjacent to each other.

When the electrode fingers 412 are varied in the pitch in the thickness direction (e.g., the pitches P1 and P2), both a main mode for main resonance and a spurious mode for a spurious wave are less likely to have resonance and phase intensity decreases in each case. However, at least one of the plate wave or the bulk wave having frequency characteristics less likely to be influenced by a pitch difference is adopted as main resonance in an embodiment of the present disclosure, so as to have less influences on frequency characteristics of main resonance even if the pitch P1 of the electrode fingers 412 in the wide regions 43 is different from the pitch P2 of the electrode fingers 412 in the narrow regions 44. Therefore, an embodiment of the present disclosure can preferably maintain the frequency characteristics of main resonance as well as can effectively reduce spuriousness.

Effects of the wide regions 43 and the narrow regions 44 can be described qualitatively in this manner, so that the width and the thickness of the electrode fingers 412 as well as the width, the thickness, and the like of the groove 21 can have any appropriate specific values. For example, at least one of T1/P or T2/P may be 0.05 or more, 0.2 or more, or 0.3 or more, and may be 0.6 or less, 0.5 or less, or 0.3 or less, and any appropriate lower and upper limits mentioned above may be combined with each other so as not to cause inconsistency. At least one of the thickness of the electrode fingers 412 or the depth of the groove 21 may be 0.005 λ or more, 0.01 λ or more, 0.02 λ or more, or 0.04 λ or more, and may be 0.5 λ or less, 0.3 λ or less, or 0.1 λ or less with proviso that its value is equal to or less than the thickness of the piezoelectric body layer 2 (or less than the thickness of the piezoelectric body layer 2), and any appropriate lower and upper limits mentioned above may be combined with each other. A larger thickness of the electrode fingers 412 is likely to achieve the structure and the effects described above of the electrode fingers 412.

FIG. 4 indicates simulation results of frequency characteristics of the acoustic wave resonator 1 according to an embodiment of the present disclosure. FIG. 4 includes a solid line indicating a simulation result according to example 1 as illustrated in FIGS. 1, 3A, and 3B, and a dotted line indicating a simulation result according to a comparative example. According to example 1, the side surfaces of the electrode fingers 412 are inclined and the embedded regions 45 of the electrode fingers 412 each have the trapezoidal sectional shape as illustrated in FIGS. 3A and 3B. According to the comparative example, the side surfaces of the electrode fingers 412 are not inclined and the embedded regions 45 each have an oblong sectional shape.

As apparent from FIG. 4, the example reduces spuriousness generated around 6000 MHz to 6500 MHz rather than the comparative example. The example has less influences on characteristics of main resonance positioned around 5400 MHz to 5800 MHz. An embodiment of the present disclosure can thus provide an acoustic wave resonator having excellent frequency characteristics.

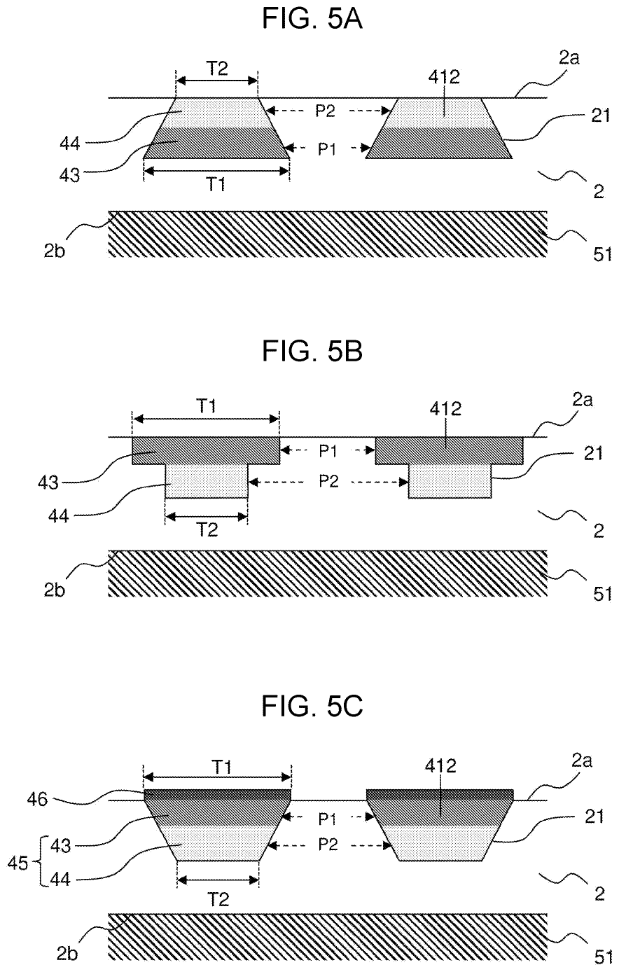

The sectional shape of the embedded region 45 in each of the electrode fingers 412 and a positional relationship between the wide region 43 and the narrow region 44 can be designed as appropriate. FIGS. 5A to 5C illustrate acoustic wave resonators 1 according to other examples of the present disclosure.

In an embodiment as illustrated in FIG. 1, the narrow region 44 is positioned closer to the lower surface 2b of the piezoelectric body layer 2 than the wide region 43. However, the positional relationship is not limited to this exemplification. FIG. 5A exemplifies the narrow regions 44 that are positioned closer to the upper surface 2a of the piezoelectric body layer 2 than the wide regions 43.

In an embodiment as illustrated in FIG. 1, the embedded region 45 of each of the electrode fingers 412 has the trapezoidal sectional shape including the lower base as the main surface positioned adjacent to the bottom of the groove 21, and the legs as the side surfaces. However, the sectional shape is not limited to this exemplification. FIG. 5B exemplarily illustrates the embedded regions 45 of the electrode fingers 412 each having a sectional shape obtained by combining the wide region 43 having an oblong shape and the narrow region 44 having an oblong shape. FIG. 5B exemplifies the narrow regions 44 that are positioned closer to the lower surface 2b of the piezoelectric body layer 2 than the wide regions 43.

An embodiment as illustrated in FIG. 1 exemplifies the electrode fingers 412 entirely positioned in the groove 21. However, positioning thereof is not limited to this exemplification. As exemplarily illustrated in FIG. 5C, the electrode fingers 412 may each include a portion positioned in the groove 21 and another portion positioned outside the groove 21. A region positioned outside the groove 21 will be referred to as the protruding region 46 of the electrode finger 412. The protruding region 46 has a width that can be set as appropriate. For example, the width of the protruding region 46 may be larger or smaller than the width of the narrow region 44 in the embedded region 45.

The protruding region 46 may be smaller in the length in the Z axis direction than the embedded region 45. In other words, a protruding amount in the protruding region 46 from the piezoelectric body layer 2 may be smaller than an embedded amount in the embedded region 45. This case more effectively reduces spuriousness in the embedded region 45.

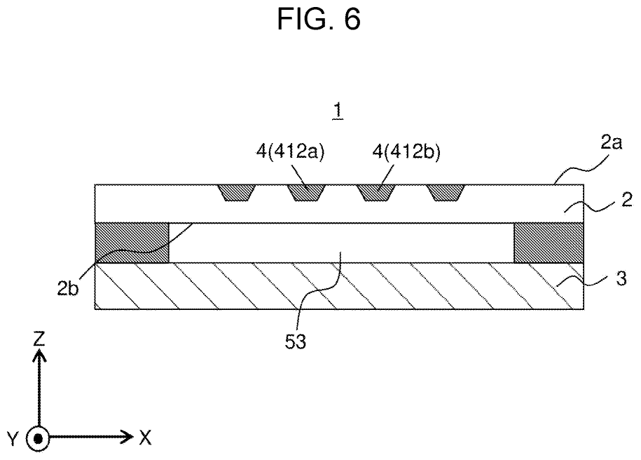

In the acoustic wave resonator 1 according to an embodiment of the present disclosure as illustrated in FIG. 1, the acoustic reflective layer 5 is exemplified as a solid layer, but is not limited to this exemplification. According to a different embodiment of the present disclosure as illustrated in FIG. 6, the piezoelectric body layer 2 and the support substrate 3 may interpose a void 53. The void 53 contains gas. The gas may be air or inert gas such as nitrogen or Argon. The support substrate 3 may be in direct or indirect contact with the piezoelectric body layer 2.

The void 53 is positioned to be overlapped with the plurality of electrode fingers 412 in a plan perspective view in the Z axis direction. In such a configuration, the gas provided in the void 53 serves as an acoustic reflective layer to effectively reduce leakage of an acoustic wave from the lower surface 2b of the piezoelectric body layer 2. The void 53 may be set as appropriate in terms of its size, depth, and the like.

When the electrode finger 412 has the trapezoidal sectional shape in the extending direction in an embodiment of the present disclosure as illustrated in FIG. 3B, the upper base 451 and the leg 453 form an angle θ that may have any appropriate value within a range less than 90 degrees. The angle θ having a larger value increases a difference between the width of the electrode finger 412 in the wide region 43 and the width of the electrode finger 412 in the narrow region 44. This eventually increases the difference between the pitch P1 of the electrode fingers 412 in the wide regions 43 and the pitch P2 of the electrode fingers 412 in the narrow regions 44, so as to more effectively reduce spuriousness.

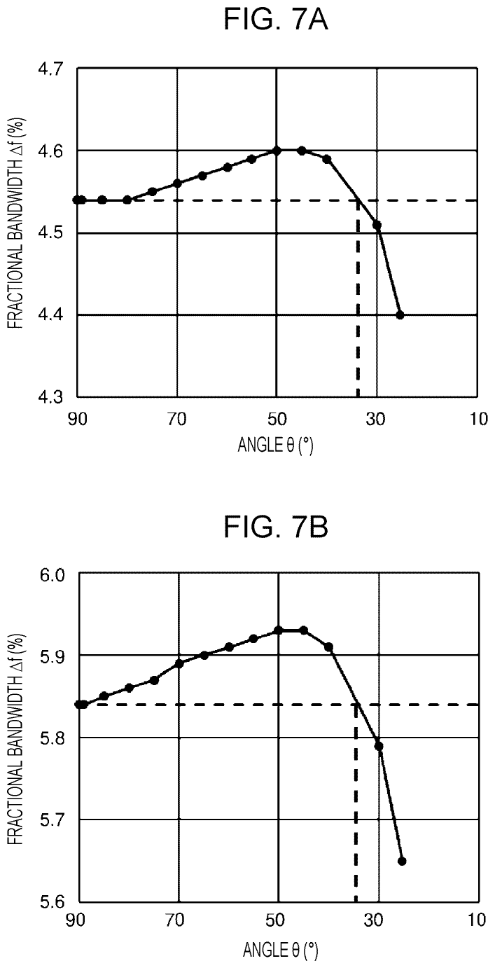

The angle θ between the upper base 451 and the leg 453 may be exemplarily within a range more than 35 degrees and less than 90 degrees. FIGS. 7A and 7B are graphs indicating simulation results of frequency characteristics with the angle θ being varied in examples 1 and 2 of an embodiment of the present disclosure. FIGS. 7A and 7B each include an ordinate axis indicating a fractional bandwidth Δf (%) of main resonance, and a transverse axis indicating the angle θ (°). In the present description, the fractional bandwidth Δf is defined as (fa−fr)×100/fr assuming that the acoustic wave resonator 1 has a resonance frequency fr and an antiresonance frequency fa. The fractional bandwidth Δf of main resonance having a larger value increases a bandwidth as a filter and improves the frequency characteristics.

FIG. 7A indicates a simulation result of the frequency characteristics according to example 1. FIG. 7B indicates a simulation result of the frequency characteristics according to example 2. Example 1 corresponds to an embodiment as illustrated in FIG. 1, and the acoustic reflective layer 5 including the low acoustic impedance layers 51 and the high acoustic impedance layers 52 being stacked is disposed adjacent to the lower surface 2b of the piezoelectric body layer 2. Example 2 corresponds to an embodiment as illustrated in FIG. 6, and the void 53 is provided adjacent to the lower surface 2b of the piezoelectric body layer 2. The piezoelectric body layer 2 contains LT in each of examples 1 and 2. Examples 1 and 2 will be detailed below in terms of designing.

Common conditions between examples 1 and 2 (piezoelectric body layer: LT, Euler angles of piezoelectric body layer: (0°, 31°, 0°), thickness of piezoelectric body layer: 0.40 μm, IDT electrode: Al, pitch P: 1.1 μm, T1/P: 0.5, electrode thickness: 0.13 μm, and support substrate: Si)
Example 1 (low acoustic impedance layers: SiO₂, high acoustic impedance layers: HfO₂)
Example 2 (void provided)

The width T1 and the electrode thickness are set constant and the width T2 is varied to vary the angle θ.

As apparent from FIGS. 7A and 7B, when the angle θ is within the range more than 35 degrees and less than 90 degrees, the fractional bandwidth Δf is larger in comparison to the case with the angle θ equal to 90 degrees. Accordingly, the angle θ within the range more than 35 degrees and less than 90 degrees can reduce spuriousness as well as can increase the fractional bandwidth Δf so as to improve the characteristics of main resonance.

The angle θ may alternatively be within a range more than 35 degrees and less than 85 degrees. The fractional bandwidth Δf can be increased more effectively in this case. The angle θ may still alternatively be within a range more than 35 degrees and less than 80 degrees. The fractional bandwidth Δf can be increased more effectively in this case. The angle θ may further alternatively be within a range more than 35 degrees and less than 70 degrees. The fractional bandwidth Δf can be increased more effectively in this case.

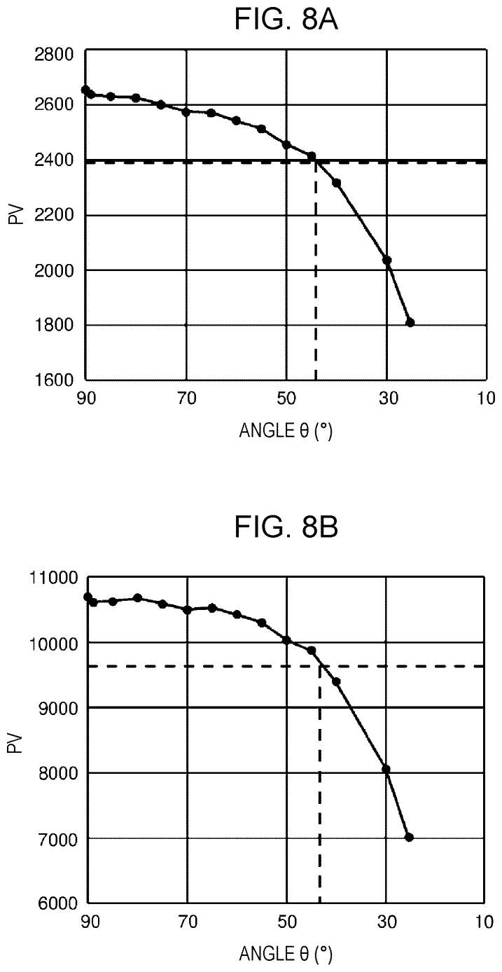

The angle θ between the upper base 451 and the leg 453 may alternatively be within a range more than 45 degrees and less than 90 degrees. FIGS. 8A and 8B are graphs indicating simulation results of frequency characteristics with the angle θ being varied in examples 1 and 2 of an embodiment of the present disclosure. FIGS. 8A and 8B each include an ordinate axis indicating a value of peak to valley PV of main resonance, and a transverse axis indicating the angle θ (°). In the present description, the PV is defined as a value obtained by dividing an absolute value |Z| of impedance in the antiresonance frequency fa of the acoustic wave resonator 1 by an absolute value |Z| of impedance in the resonance frequency fr. In other words, the PV is defined such that PV=(|Z| in fa)/(|Z| in fr). The PV of main resonance having a larger value achieves more excellent sharp characteristics and loss characteristics as a filter and improves the frequency characteristics.

FIG. 8A indicates a simulation result of the frequency characteristics according to example 1. FIG. 8B indicates a simulation result of the frequency characteristics according to example 2.

As apparent from FIGS. 8A and 8B, when the angle θ is within the range more than 45 degrees and less than 90 degrees, the PV increases as in the case with the angle θ equal to 90 degrees. Accordingly, the angle θ within the range more than 45 degrees and less than 90 degrees can reduce spuriousness as well as can increase the PV so as to improve the characteristics of main resonance.

The angle θ may alternatively be within a range more than 45 degrees and less than 85 degrees. The PV can be increased more effectively in this case. The angle θ may still alternatively be within a range more than 45 degrees and less than 80 degrees. The PV can be increased more effectively in this case. The angle θ may further alternatively be within a range more than 45 degrees and less than 70 degrees. The PV can be increased more effectively in this case.

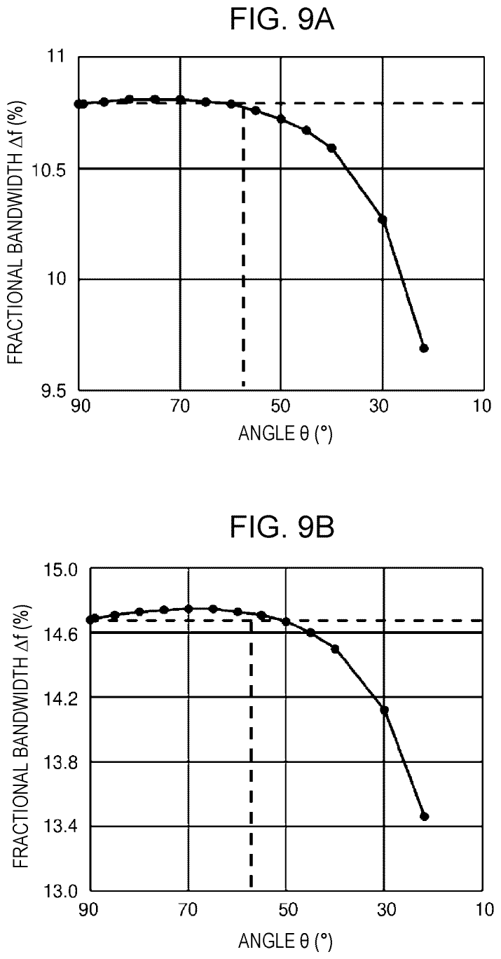

The angle θ between the upper base 451 and the leg 453 may be exemplarily within a range more than 55 degrees and less than 90 degrees. FIGS. 9A and 9B are graphs indicating simulation results of frequency characteristics with the angle θ being varied in examples 3 and 4 of an embodiment of the present disclosure. FIGS. 9A and 9B each include an ordinate axis indicating the fractional bandwidth Δf (%) of main resonance, and a transverse axis indicating the angle θ (°).

FIG. 9A indicates a simulation result of the frequency characteristics according to example 3. FIG. 9B indicates a simulation result of the frequency characteristics according to example 4. Example 3 corresponds to an embodiment as illustrated in FIG. 1, and the acoustic reflective layer 5 including the low acoustic impedance layers 51 and the high acoustic impedance layers 52 being stacked is disposed adjacent to the lower surface 2b of the piezoelectric body layer 2. Example 4 corresponds to an embodiment as illustrated in FIG. 6, and the void 53 is provided adjacent to the lower surface 2b of the piezoelectric body layer 2. The piezoelectric body layer 2 contains LN in each of examples 3 and 4. Examples 3 and 4 will be detailed below in terms of designing.

Common conditions between examples 3 and 4 (piezoelectric body layer: LN, Euler angles of piezoelectric body layer: (0°, 35°, 0°), thickness of piezoelectric body layer: 0.37 μm, IDT electrode: Al, pitch P: 1.1 μm, T1/P: 0.5, electrode thickness: 0.11 μm, and support substrate: Si)
Example 3 (low acoustic impedance layers: SiO₂, high acoustic impedance layers: HfO₂)
Example 4 (void provided)

The width T1 and the electrode thickness are set constant and the width T2 is varied to vary the angle θ.

As apparent from FIGS. 9A and 9B, when the angle θ is within the range more than 55 degrees and less than 90 degrees, the fractional bandwidth Δf is larger (or equal) in comparison to the case with the angle θ equal to 90 degrees. Accordingly, the angle θ within the range more than 55 degrees and less than 90 degrees reduces spuriousness as well as increases the fractional bandwidth Δf so as to improve the characteristics of main resonance.

The angle θ may alternatively be within a range more than 55 degrees and less than 85 degrees. The fractional bandwidth Δf can be increased more effectively in this case. The angle θ may still alternatively be within a range more than 55 degrees and less than 80 degrees. The fractional bandwidth Δf can be increased more effectively in this case. The angle θ may further alternatively be within a range more than 55 degrees and less than 70 degrees. The fractional bandwidth Δf can be increased more effectively in this case.

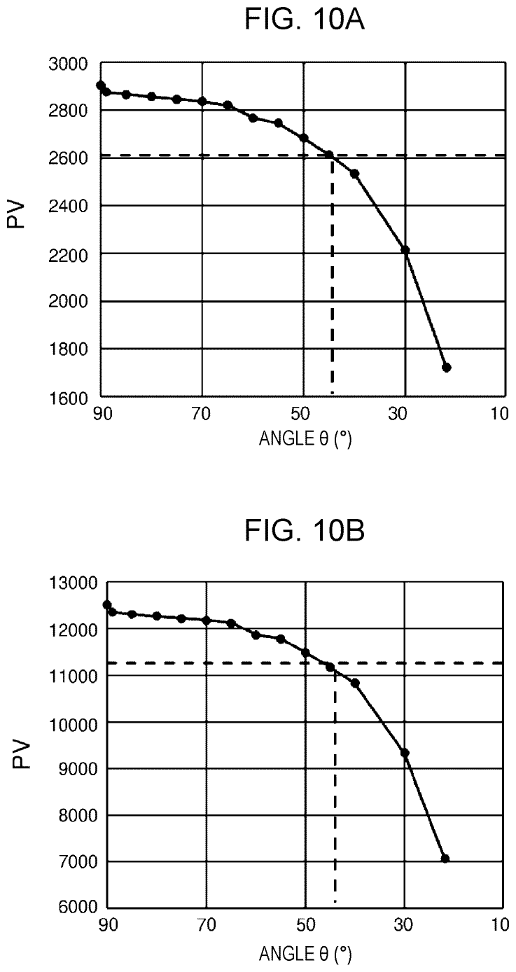

The angle θ between the upper base 451 and the leg 453 may alternatively be within the range more than 45 degrees and less than 90 degrees. FIGS. 10A and 10B are graphs indicating simulation results of frequency characteristics with the angle θ being varied in examples 3 and 4 of an embodiment of the present disclosure. FIGS. 10A and 10B each include an ordinate axis indicating the value of the PV of main resonance, and a transverse axis indicating the angle θ (°).

FIG. 10A indicates a simulation result of the frequency characteristics according to example 3. FIG. 10B indicates a simulation result of the frequency characteristics according to example 4.

As apparent from FIGS. 10A and 10B, when the angle θ is within the range more than 45 degrees and less than 90 degrees, the PV increases as in the case with the angle θ equal to 90 degrees. Accordingly, the angle θ within the range more than 45 degrees and less than 90 degrees can reduce spuriousness as well as can increase the PV so as to improve the characteristics of main resonance.

The angle θ may alternatively be within the range more than 45 degrees and less than 85 degrees. The PV can be increased more effectively in this case. The angle θ may still alternatively be within the range more than 45 degrees and less than 80 degrees. The PV can be increased more effectively in this case. The angle θ may further alternatively be within the range more than 45 degrees and less than 70 degrees. The PV can be increased more effectively in this case.

Though not particularly illustrated, the applicant have confirmed through simulated calculations that spuriousness can be reduced effectively also under the conditions of examples 1 to 4 with the pitch P set to 5 μm and T1/P set to 0.06.

The “trapezoidal shape” does not necessarily have a strictly trapezoidal shape. For example, a trapezoid may include rounded corners. The upper base, the lower base, and the legs do not necessarily have strictly straight shapes. The upper base, the lower base, and the legs may exemplarily have rounded curved shapes. In this case, the angle θ between the upper base and the leg may be exemplarily obtained as an angle formed between a tangent at a midpoint of the upper base and a tangent at a midpoint of the leg.

The trapezoid may be partially provided with a concave portion or a convex portion. In this case, the angle θ between the upper base and the leg may be exemplarily obtained as an angle formed between a line substantially overlapped with a portion excluding the partial concave or convex portion in the upper base and a line substantially overlapped with a portion excluding the partial concave or convex portion in the leg.

The sectional shape of each of the electrode fingers 412 can be obtained in accordance with any one of various methods. For example, the groove 21 is formed in the piezoelectric body layer 2 to have a desired sectional shape such as a trapezoidal shape. Subsequently formed is a metal layer constituting the electrode finger 412. When the metal layer is filled in the groove 21 in this case, the sectional shape o the electrode finger 412 becomes equal to the sectional shape of the groove 21 so as to have a desired shape such as the trapezoidal shape. The groove 21 having the desired sectional shape can also be formed in accordance with any one of various methods. The groove 21 may be exemplarily formed by etching (e.g., wet etching). Anisotropy of a single crystal to etching may be utilized or etchings may be sequentially executed under different conditions to obtain the sectional shape such as the trapezoidal shape. The groove 21 may alternatively be formed by laser beam machining or the like. A tapered shape or a reverse tapered shape of a laser beam may be utilized or etchings may be sequentially executed under different conditions to obtain the sectional shape such as the trapezoidal shape.

### Exemplary Utilization of Acoustic Wave Resonator 1: Branching Filter

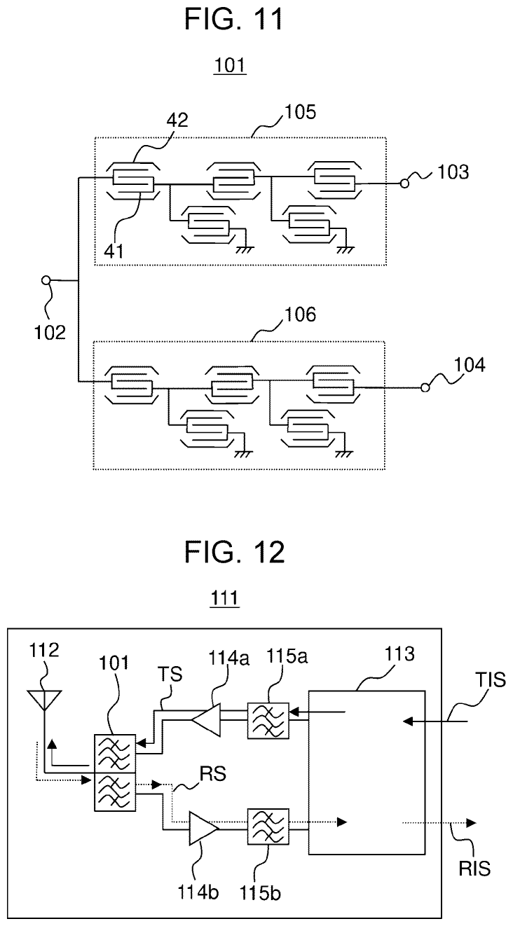

FIG. 11 is a circuit diagram schematically illustrating a configuration of a branching filter 101 exemplarily utilizing the acoustic wave resonator 1. As comprehended from reference signs indicated in an upper left portion of the sheet of the figure, FIG. 11 schematically illustrates the comb-shaped electrode 41 in a two forked shape, and the reflectors 42 each indicated by a single line bent at both ends.

The branching filter 101 exemplarily includes a transmission filter 105 configured to filter a signal transmitted from a transmission terminal 103 and output the signal thus filtered to an antenna terminal 102, and a reception filter 106 configured to filter a signal received from the antenna terminal 102 and output the signal thus filtered to a reception terminal 104.

Each of the transmission filter 105 and the reception filter 106 is exemplarily constituted by a ladder filter including a plurality of resonators connected in a ladder form. That is, the transmission filter 105 includes one or more serial resonators connected in series between the transmission terminal 103 and the antenna terminal 102, and one or more parallel resonators connecting a serial arm thereof and reference potential.

According to an embodiment of the present disclosure, the acoustic wave resonator 1 may be exemplarily utilized as at least one of the serial resonator or the parallel resonator included in each of the transmission filter 105 and the reception filter 106.

FIG. 11 merely illustrates an exemplary configuration of the branching filter 101, and the branching filter 101 is not limited to the configuration illustrated in FIG. 11. For example, the transmission filter 105 may alternatively be constituted by a multi-mode filter. In FIG. 11, each of the transmission filter 105 and the reception filter 106 is an acoustic wave filter, but is not limited to this configuration. For example, one of the transmission filter 105 and the reception filter 106 may be an acoustic wave filter including the acoustic wave resonator 1, and the other one may be an LC filter including one or more inductors and one or more capacitors.

Described above is the branching filter 101 including the transmission filter 105 and the reception filter 106, but the branching filter 101 is not limited to this configuration. The branching filter 101 may be a diplexer, a multiplexer including three or more filters, or the like.

### Exemplary Utilization of Acoustic Wave Resonator 1: Communication Device

FIG. 12 is a block diagram illustrating a principal part of a communication device 111 exemplarily utilizing the acoustic wave resonator 1 and the branching filter 101. The communication device 111 includes the branching filter 101 and is configured to execute radio communication utilizing radio waves.

The communication device 111 includes a radio frequency integrated circuit (RF-IC) 113 that modulates and increases a frequency of a transmission information signal TIS including information to be transmitted so as to obtain a transmission signal TS. A bandpass filter 115a removes an unwanted component other than a transmission passband in the transmission signal TS that is amplified by an amplifier 114a and is transmitted to the transmission terminal 103. The transmission filter 105 removes the unwanted component other than the transmission passband in the transmission signal TS thus received and outputs the transmission signal TS obtained by such removal from the antenna terminal 102 to an antenna 112. The antenna 112 converts the transmission signal TS thus received to a radio signal and transmits the radio signal.

In the communication device 111, the antenna 112 converts the radio signal thus received to a reception signal RS to be received by the antenna terminal 102. The reception filter 106 removes an unwanted component other than a reception passband in the reception signal RS thus received and outputs the reception signal RS thus obtained from the reception terminal 104 to an amplifier 114b. The amplifier 114b amplifies the reception signal RS thus outputted, and a bandpass filter 115b removes the unwanted component other than the reception passband in the reception signal RS. The RF-IC 113 decreases a frequency of the reception signal RS and modulates the reception signal RS to obtain a reception information signal RIS.

The transmission information signal TIS and the reception information signal RIS may be low-frequency signals including appropriate information, and examples thereof include an analog audio signal and a digitized audio signal. A radio signal passband may be set as appropriate, and a relatively high-frequency passband is also applicable to an embodiment of the present disclosure. Examples of a modulation technique include phase modulation, amplitude modulation, frequency modulation, and any combination of two or more of these modulation techniques. FIG. 12 exemplifies a direct conversion system as a circuit system, which is not limited to this exemplification and examples of which include a double-superheterodyne system. FIG. 12 schematically illustrates only a principal part. A low-pass filter or an isolator may be additionally disposed at an appropriate position, and the amplifier and the like may be relocated.

### REFERENCE SIGNS

1 acoustic wave resonator
2 piezoelectric body layer
2a upper surface (first surface)
2b lower surface (second surface)
21 groove
3 support substrate
4 IDT electrode
41 comb-shaped electrode
411 bus bar
412 electrode finger (first electrode finger)
42 reflector
43 wide region
44 narrow region
45 embedded region
46 protruding region
451 upper base
452 lower base
453 leg
5 acoustic reflective layer
51 low acoustic impedance layer
52 high acoustic impedance layer
53 void
101 branching filter
102 antenna terminal
103 transmission terminal
104 reception terminal
111 communication device
112 antenna
113 RF-IC
114 amplifier
115 bandpass filter

1. An acoustic wave resonator comprising:
a piezoelectric body layer including a first surface provided with a groove, and having piezoelectric properties; and
a plurality of electrode fingers including a first electrode finger at least partially positioned in the groove; wherein
In a sectional view as viewed in an extension direction of the plurality of electrode fingers, a region of the first electrode finger positioned in the groove includes a wide region and a narrow region smaller in width than the wide region, and
the acoustic wave resonator excites at least one of a plate wave or a bulk wave as main resonance.

2. The acoustic wave resonator according to claim 1, wherein
the piezoelectric body layer includes a second surface positioned opposite to the first surface, and
the narrow region is positioned closer to the second surface than the wide region.

3. The acoustic wave resonator according to claim 1, wherein
in the sectional view, the first electrode finger has a trapezoidal shape including an upper base as a surface positioned adjacent to an opening of the groove, a lower base as a surface positioned adjacent to a bottom of the groove, and legs as side surfaces.

4. The acoustic wave resonator according to claim 3, wherein
in the sectional view, the upper base and each of the legs form an angle within a range more than 35 degrees and less than 90 degrees.

5. The acoustic wave resonator according to claim 3, wherein
in the sectional view, the upper base and each of the legs form an angle within a range more than 45 degrees and less than 90 degrees.

6. The acoustic wave resonator according to claim 3, wherein
in the sectional view, the upper base and each of the legs form an angle within a range more than 55 degrees and less than 90 degrees.

7. The acoustic wave resonator according to claim 1, wherein
a Lamb wave in an A1 mode is excited as main resonance.

8. The acoustic wave resonator according to claim 1, wherein
the piezoelectric body layer has a thickness equal to or less than twice a repetition interval of the plurality of electrode fingers.

9. The acoustic wave resonator according to claim 1, wherein
the piezoelectric body layer contains lithium tantalate or lithium niobate.

10. The acoustic wave resonator according to claim 1, the acoustic wave resonator further comprising
an acoustic reflective layer in direct or indirect contact with the piezoelectric body layer, wherein
the acoustic reflective layer includes a plurality of low acoustic impedance layers lower in acoustic impedance than the piezoelectric body layer and a plurality of high acoustic impedance layers higher in acoustic impedance than the plurality of low acoustic impedance layers, and the low acoustic impedance layers and the high acoustic impedance layers are stacked alternately.

11. The acoustic wave resonator according to claim 1, the acoustic wave resonator further comprising
a support substrate in direct or indirect contact with the piezoelectric body layer, wherein
the piezoelectric body layer and the support substrate interpose a void, and
the void overlaps the plurality of electrode fingers in a plan perspective view in a direction perpendicular to the first surface.

12. A communication device comprising:
an antenna;
an acoustic wave filter connected to the antenna; and
an IC connected to the acoustic wave filter; wherein
the acoustic wave filter includes the acoustic wave resonator according to claim 1.

13. The acoustic wave resonator according to claim 2, wherein
in the sectional view, the first electrode finger has a trapezoidal shape including an upper base as a surface positioned adjacent to an opening of the groove, a lower base as a surface positioned adjacent to a bottom of the groove, and legs as side surfaces.

14. The acoustic wave resonator according to claim 2, wherein
a Lamb wave in an A1 mode is excited as main resonance.

15. The acoustic wave resonator according to claim 3, wherein
a Lamb wave in an A1 mode is excited as main resonance.

16. The acoustic wave resonator according to claim 4, wherein
a Lamb wave in an A1 mode is excited as main resonance.

17. The acoustic wave resonator according to claim 5, wherein
a Lamb wave in an A1 mode is excited as main resonance.

18. The acoustic wave resonator according to claim 6, wherein
a Lamb wave in an A1 mode is excited as main resonance.

19. The acoustic wave resonator according to claim 2, wherein
the piezoelectric body layer has a thickness equal to or less than twice a repetition interval of the plurality of electrode fingers.

20. The acoustic wave resonator according to claim 3, wherein
the piezoelectric body layer has a thickness equal to or less than twice a repetition interval of the plurality of electrode fingers.
